(19) United States
(12) Patent Application Publication
(10) Pub. No.: US 2024/0222210 A1
(43) Pub. Date: Jul. 4, 2024

(54) GLASS SUBSTRATE FABRICATION USING HYBRID BONDING

(71) Applicant: Intel Corporation, Santa Clara, CA (US)

(72) Inventors: Bohan Shan, Chandler, AZ (US); Haobo Chen, Chandler, AZ (US); Bai Nie, Chandler, AZ (US); Srinivas Venkata Ramanuja Pietambaram, Chandler, AZ (US); Gang Duan, Chandler, AZ (US); Kyle Jordan Arrington, Gilbert, AZ (US); Ziyin Lin, Chandler, AZ (US); Hongxia Feng, Chandler, AZ (US); Yiqun Bai, Chandler, AZ (US); Xiaoying Guo, Chandler, AZ (US); Dingying Xu, Chandler, AZ (US); Kristof Darmawikarta, Chandler, AZ (US)

(73) Assignee: Intel Corporation, Santa Clara, CA (US)

(21) Appl. No.: 18/091,548

(22) Filed: Dec. 30, 2022

(51) Int. Cl. H01L 23/15; H01L 21/48; H01L 23/498

(52) U.S. Cl. CPC H01L 23/15; H01L 21/486; H01L 23/49822; H01L 23/49827; H01L 23/49838

(57) ABSTRACT

An integrated circuit device substrate includes a first glass layer, a second glass layer, and a dielectric interface layer between the first glass layer and the second glass layer. A plurality of conductive pillars extend through the first glass layer, the dielectric layer and the second glass layer, wherein the conductive pillars taper from a first diameter in the dielectric layer to a second diameter in the first glass layer and the second glass layer, and wherein the first diameter is greater than the second diameter.

### TECHNICAL FIELD

Embodiments described herein generally relate to substrates for mounting semiconductor devices. The substrates include glass panels that utilize hybrid bonding interconnections, methods for making the glass panels, and methods for mounting integrated circuit devices on the glass panels.

### BACKGROUND

An integrated circuit device (IC), which may also be referred to as a chip, microchip or microelectronic circuit, is a semiconductor wafer on which thousands or millions of tiny resistors, capacitors, diodes and transistors are fabricated. In some examples, an IC can function as an amplifier, oscillator, timer, counter, logic gate, computer memory, microcontroller or microprocessor.

Circuit boards for mounting integrated circuit devices have been made from glass fiber reinforced epoxy or phenolic resins. Current integrated circuit package designs may require circuit boards having vias at a pitch of less than about 200 microns, and in some examples the glass fiber reinforced resins are not sufficiently dimensionally stable to support such small and closely spaced apertures.

To provide accurate and reproducible vias through a circuit board at very small pitches, some integrated circuit package designs utilize glass core materials, which have a lower coefficient of thermal expansion (CTE), and can be made flatter, than glass fiber reinforced resin circuit boards.

To achieve increasingly aggressive input/output (I/O)) speed targets, some integrated circuit packages utilize optical interconnect technology. In these packages, photonic integrated circuit (PIC) devices should be precisely mounted on the circuit board to reduce optical signal loss. Attaching integrated circuit devices and modules such as, for example, photonic integrated circuit devices (PICs) or electrical integrated circuit devices (EICs), can require formation of multiple cavities on a substrate, and precise attachment of redistribution layers (RDL) to the substrate, as well as a multi-level die bonding process. Accurate and reproducible RDL patterning on a surface with large cavities presents challenges in the fabrication process, and clean cavities in a substrate can be difficult to maintain as a workpiece undergoes multiple process steps.

Glass circuit board designs and assembly techniques are needed to provide through vias and the conductive pillars therein at a small pitch, and to provide accurate and reproducible mounting of integrated circuit devices, particularly photonic integrated circuit devices.

### BRIEF DESCRIPTION OF THE DRAWINGS

FIG. 1 is a schematic cross-sectional view of a substrate for an integrated circuit device including tapering conductive vias through a glass panel.

FIG. 2A is a schematic, cross-sectional view of a substrate including a glass panel with at least one cavity for mounting an integrated circuit device such as a photonic integrated circuit device.

FIG. 2B is an overhead view of the substrate of FIG. 2A.

FIGS. 3A-3F are schematic, cross-sectional views of a process for making a substrate for mounting an integrated circuit device using glass panels and hybrid bonding techniques according to an example embodiment.

FIG. 3G is a flow diagram of the process of FIGS. 3A-3F in accordance with some example embodiments.

FIGS. 4A-4D are schematic, cross-sectional views of a process for making a substrate for mounting an integrated circuit device using glass panels and hybrid bonding techniques, according to an example embodiment.

FIG. 4E is a flow diagram of the process of FIGS. 4A-4D in accordance with some example embodiments.

FIGS. SA-SE are schematic, cross-sectional views of a process for making a substrate for mounting an integrated circuit device using glass panels and photonic heating, according to an example embodiment.

FIG. 5F is a flow diagram of the process of FIGS. 5A-SE in accordance with some example embodiments.

FIG. 6 shows a system that may incorporate the glass panel constructions of the present disclosure and methods for making them, in accordance with some example embodiments.

Like symbols in the figures indicate like elements.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Through glass vias (TGV) in glass circuit boards can be formed using laser treatment of a glass core followed by etching to form apertures through the glass core. Seeds are then deposited in the apertures using, for example, a sputtering process, followed by metal plating to form conductive passages through the glass core.

In some examples, the glass panels are irradiated with a laser to form a patterned via array, and the glass panels are subsequently etched to form vias extending from a first major surface to an opposed second major surface thereof. The etched vias are seeded with a metal or metal alloy and then plated to form electrically conductive pillars. Referring to the schematic cross-sectional view of FIG. 1, a glass panel 10 includes a glass core 12 with a substantially planar first major surface 14 and an opposed substantially planar second major surface 16. An array 18 of conductive pillars 20 formed in vias 22 extends from the first major surface 14 to the second major surface 16 of the glass panel 12. The conductive pillars 16 gradually taper from a first diameter d₁ at the major surfaces 14, 16 to a second diameter d₂ within the glass core 12, wherein d₁>d₂.

The bottle-necked structure of the conductive pillars 20 can result from large aspect ratios of the patterned vias 22 in glass core 12 with large thicknesses t, or may result from seed deposition, and plating qualities used to form the pillars 20. For example, if the vias 22 are not sufficiently tapered within the glass core 12, plating along the walls 24 of the vias 22 can be discontinuous. In some cases, this necked structure within the pillars 20 can cause additional risk for high current density and self-heating of the glass core 12.

In one aspect, the present disclosure is directed to methods for making glass substrates, suitable for mounting integrated circuit devices, which utilize multiple thin glass panels that are bonded together at a dielectric interface. In some examples, the facing dielectric layers on each glass panel are bonded together using a hybrid bonding process, which may also be referred to as direct bond interconnect (DBI). In this application the term hybrid bonding refers to an extension of direct bonding, whereby two appropriately prepared dielectric surfaces on components form a bond after being brought into contact with one another at ambient temperature. For example, some dielectric materials have a high density of surface functional groups that can form a bond when brought into contact.

In some examples, the facing dielectric surfaces on the components to be bonded include an arrangement or an array of conductive interconnects patterned in the dielectric field, and bonding takes place in two steps.

First, when the components are contacted, the facing dielectric layers on each component contact each other, and the patterned conductive interconnects on each device also contact each other. A low temperature dielectric bond is formed between the adjacent dielectric layers at ambient temperature. Next, the dielectrically bonded components are annealed at about 100° C. to about 500° C. or about 200° ° C. to about 400° ° C., which maximizes dielectric bond strength and induces expansion of the abutting conductive interconnects to form electrical interconnections between them.

The hybrid bonded multiple thin glass panels of the present disclosure provide through vias and continuous conductive pillars that do not taper to a smaller diameter within the hybrid bonded glass panel. The glass panels of the present disclosure can provide advantages including, but not limited to, reduced current limitations in the conductive pillars, reduced self-heating of the glass panel, and a simplified via formation process for greater reproducibility. In some examples, conductive pillars with a smaller pitch may be more easily patterned on a thinner glass panel.

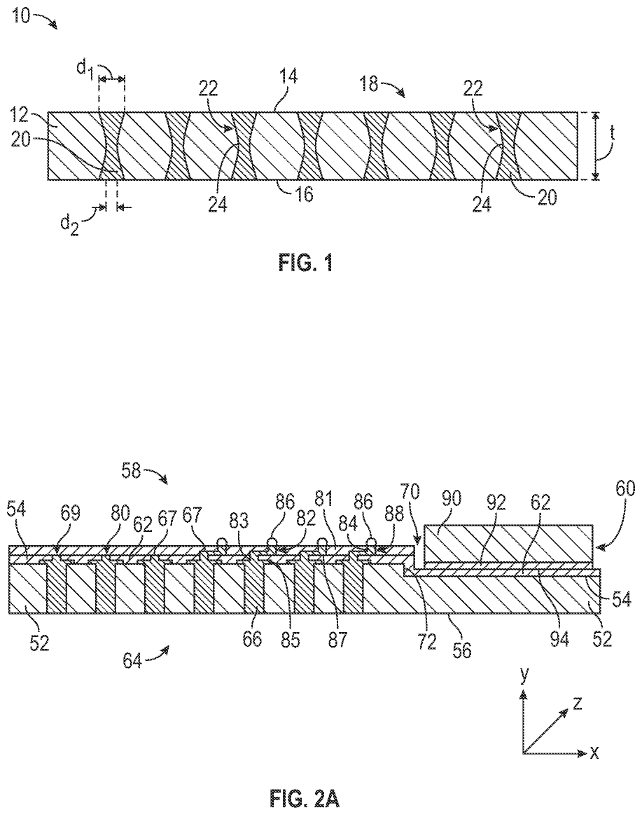

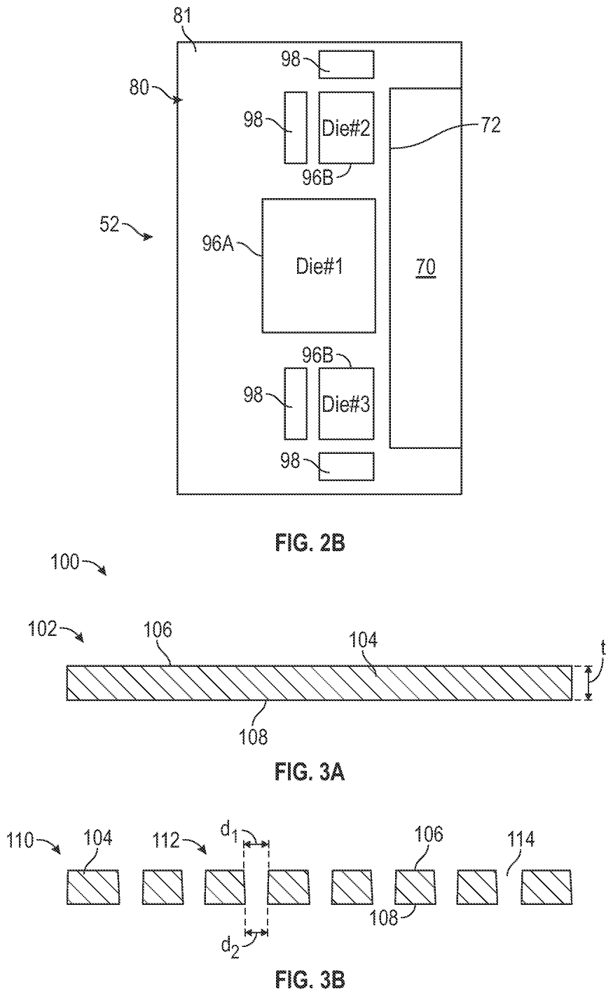

To achieve increasingly aggressive input/output (I/O) speed targets, glass panels can be used to mount integrated circuit modules including photonic components that utilize optical interconnect technology. Referring now to the example of FIGS. 2A-2B, a glass core 52 includes a first major surface 54 and an opposed second major surface 56. The first major surface 54 includes a redistribution layer (RDL) mounting region 58 and a mounting region 60 for a photonic integrated circuit device (PIC). In this application, the term photonic integrated circuit device refers to any integrated circuit device that includes an optical component. In some examples, which are not intended to be limiting, photonic integrated circuit devices can include EICs, PICs, logic dies, combinations thereof, or stacks or modules including one or more of these components. A first dielectric layer 62 overlies the RDL mounting region 58 and the photonic integrated circuit device (PIC) mounting region 60.

The RDL mounting region 58 includes an array 64 of conductive pillars 66 that extend from the first major surface 54 to the second major surface 56 along a y direction normal to an xz plane of the glass core substrate 52 in FIG. 2A. At least a portion of the conductive pillars 64 include interconnect structures 69 that extend beyond the first dielectric layer 62 and form conductive contacts 67. As shown in FIG. 2A, the interconnect structures 69 may include a wide variety of conductive elements 82 extending along any of the x, y, and z directions as needed to make electrical connections to the pillars 66, and the structures 69 shown in FIG. 2A are merely provided as examples. In some examples, the conductive interconnect structures may include posts 83 extending along the y direction, linear bars 85 extending along the =direction, traces 87 extending along the x, y or z direction, or any combination thereof necessary to mount one or more integrated circuit devices on the RDL 80.

The PIC mounting region 60 includes a cavity 70 in the glass substrate 52. In some examples, the cavity 70 is optionally at least partially bounded by a wall 72.

A redistribution layer (RDL) 80 resides on the RDL mounting region 58 of the glass core substrate 52. The RDL 80 includes a dielectric layer 81 and conductive interconnect structures 88, at least some of which terminate in solder bump mounts 84. At least a portion of the solder bump mounts 84 are attached to solder bumps 86 suitable for connection to other dies, conductive traces, and the like.

In the example of FIG. 2A, a photonic integrated circuit device or module 90 is mounted in the PIC mounting region 60 of the glass substrate 52. The photonic integrated circuit device 90 may be mounted in the cavity 70 along the wall 72 using a wide variety of techniques, including the use of solder bumps (not shown in FIG. 2A).

Referring now to FIG. 2B, an overhead view of an example of the construction of FIG. 2A, which is not intended to be limiting, includes an arrangement of integrated circuit devices 96A, 96B mounted on the RDL layer 80. The integrated circuit devices include a logic die 96A, as well as EIC dies 96B suitable for controlling the photonic integrated circuit device 90 (FIG. 2A). For example, the dies 96A, 96B may be mounted to the RDL layer 80 using the solder balls 86 in the RDL 80. To ensure accurate transmission of optical signals from the photonic integrated circuit device 90 to the other components mounted on the RDL layer 80, the glass substrate 52 also includes an arrangement of cavities 98.

In some examples, incorporating a photonic integrated circuit device 90 into a glass core 52 can require formation of multiple cavities 98 in the glass core substrate 52. The RDL layer 80, the logic and EIC dies 96A,B. and the photonic integrated circuit device 90 should be precisely mounted on multiple levels above and within the cavity 70. RDL patterning on a surface with large cavities can be difficult, it can be difficult to prevent contamination of the cavities 70, 98 through a multi-step assembly process.

In another aspect, the present disclosure is directed to methods for mounting photonic integrated circuit devices that utilize multiple glass substrate layers attached via hybrid bonding. In one example, a first glass substrate includes conductive pillars and the RDL is formed on a second glass substrate. The first and second glass substrates are bonded to each other via hybrid bonding, which in some examples can obviate the need for formation and alignment of multiple substrate layers. The RDL can be formed on a separate substrate in a separate process, which can improve component yield. Since the first and the second glass core substrates are relatively flat, hybrid bonding of the photonic die component together with as-needed chemical mechanical polishing (CMP) can provide optimized flatness control.

Referring again to the example of FIG. 2A-2B, the photonic integrated circuit device 90 should be mounted with high position accuracy to reduce optical signal loss. In one example, the photonic integrated circuit device 90 includes a dielectric layer 92, which may be electrically connected to the glass substrate 52 using solder joints (not shown in FIG. 2A-B). However, once the photonic integrated circuit device 90 is bonded, substrate heating during downstream process steps may soften the solder joints and cause undesirable movement of the device 90. This movement can result in misalignment of the photonic integrated circuit device 90 in the cavity 70, which can potentially increase optical signal loss.

In another aspect, the present disclosure is directed to methods for enhancing the reliability of the electrical interconnect to any integrated circuit device including, but not limited to, a photonic integrated circuit device. In one example, methods of the present disclosure utilize a solder that forms a post-reflow solder joint including an intermetallic compound. The solder joint including the intermetallic compound has a melting temperature greater than about 400° C. The elevated melting temperature of the solder joint is resistant to reflow during downstream process and heating steps.

In some examples, the glass core substrate underlying an integrated circuit device mounting region includes window regions arranged such that an irradiating photonic signal can be directed to a desired location at an interface between the integrated circuit device and the glass substrate. In some examples, the solder joint including the intermetallic bond forms a more reliable bonding for the integrated circuit device, which can survive downstream assembly processes such as, for example, thermocompression bonding (TCB) or reflow.

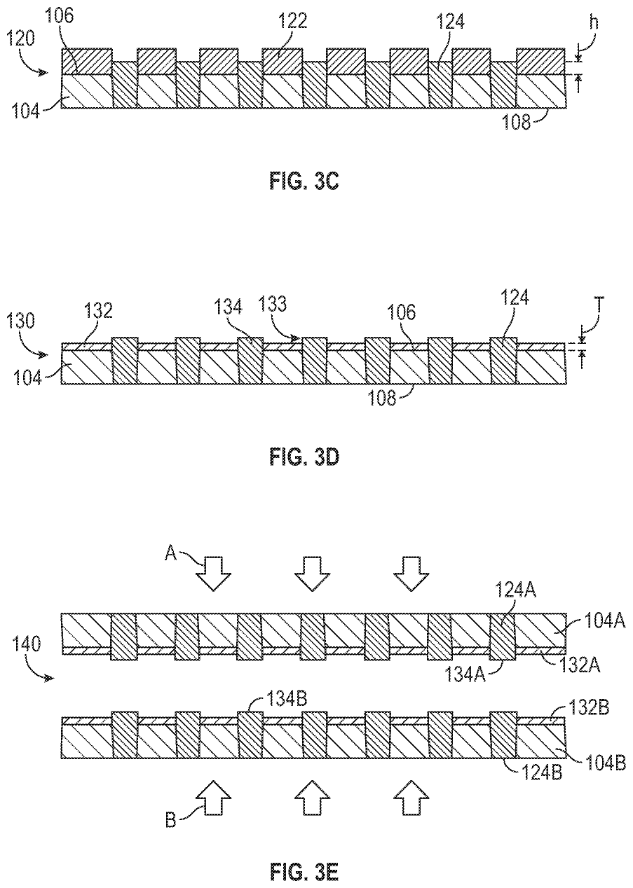

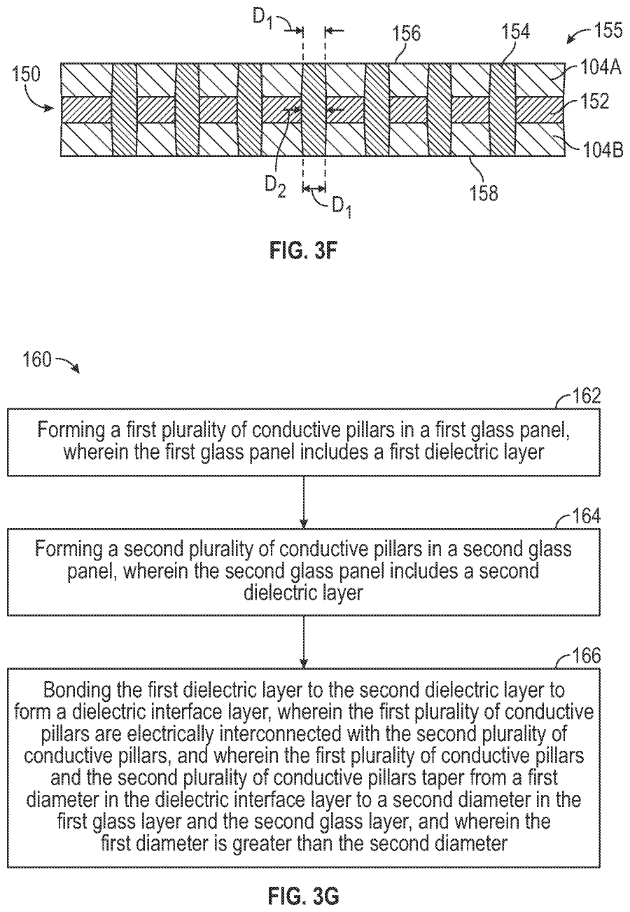

Referring now to FIG. 3A, in a process 100 for making a workpiece for mounting a semiconductor device, in an initial step 102 a glass core substrate panel 104 is selected that has a first major surface 106 and a second major surface 108. The first major surface 106 and the second major surface 108 of the glass panel 104 are planar and substantially flat, and substantially parallel to each other. In some examples, the glass panel 104 has a thickness t of about 300 microns to about 600 microns, or about 400 microns to about 500 microns. The thickness of the glass panel 104 is thus approximately half the thickness of a conventional glass panel used as a substrate for mounting semiconductor devices, which in some examples can have a thickness of about 800 microns to about 1000 microns.

In the present application, the term “glass” refers to an amorphous solid. Examples of glass materials that may be used with the described embodiments include pure silica (e.g., approximately 100% SiO₂), soda-lime glass, boro-silicate glass, and alumo-silicate glass. However, the disclosed embodiments are not limited to silica-based glass compositions, and glasses having alternative base materials (e.g., fluoride glasses, phosphate glasses, chalcogen glasses, etc.) may also be used.

Further, any combination of other materials and additives may be combined with silica (or other base material) to form a glass panel 104 having desired physical properties. Examples of these additives include not only calcium carbonate (e.g., lime) and sodium carbonate (e.g., soda), but also magnesium, calcium, manganese, aluminum, lead, boron, iron, chromium, potassium, sulfur, and antimony, as well as carbonates and/or oxides of these and other elements. These glasses and additives are but a few examples of the many types of materials and material combinations that may find application with the disclosed embodiments. In addition, the glass panel 104 may optionally include surface treatments and/or coatings to improve strength and/or durability, and a glass body suitable for use in the embodiments described herein may also be annealed to lower internal stresses.

Generally, as used herein, the term “glass” does not refer to organic polymer materials, which may be amorphous in solid form. However, it should be understood that a glass according to some embodiments may include carbon as one of the material's constituents. For example, soda-lime glass, as well as numerous variations of this glass type, include carbon.

Referring now to FIG. 3B, in step 110 of the process 100, a plurality of vias 114 is formed in the glass panel 104. In some examples, the plurality of vias 114 may be arranged in a regular or an irregular array 112. The vias may be formed by any suitable procedure, and in some examples may be formed by laser drilling, or by laser treatment of the glass panel 104 followed by wet or dry etching the glass panel 104 to provide vias 114 of a desired diameter. In one example, following laser treatment of a surface of the glass panel 104, a reactive ion etching step is performed to create the vias 114. In some examples, the glass panel may be mounted on or supported in a jig or a carrier (not shown in FIG. 3B) during via formation.

As shown in FIG. 3B, the vias 114 extend from the first major surface 106 to the second major surface 108 of the glass panel 104. As shown in the schematic of FIG. 3B, the vias 114 taper from a first diameter d₁ at the first major surface 106 to a second diameter d₂ at the second major surface 108, wherein d₁>d₂.

In some examples, which are not intended to be limiting, the vias 114 in the array 112 have a pitch of less than about 50 microns, or less than about 20 microns, or less than about 10 microns, or less than about 5 microns. Since the glass panels 104 are substantially thinner than glass panels normally used to mount semiconductor devices, the vias 114 in the array 112 are formed at a lower aspect ratio, which in some examples can improve via uniformity and reduce via pitch in the array 112.

In step 120 shown in FIG. 3C, a photoresist layer 122 is applied on the first major surface 106 of the glass panel 104, and seed layers of a conductive material such as, for example, Cu, are deposited in the vias 114 and melted to form conductive pillars 124 therein. The conductive pillars 124 extend from the first major surface 106 to the second major surface 108 of the glass panel 104, and extend to a height h above the first major surface 106. The conductive pillars 124 may be formed from any conductive material, and in some examples the pillars 124 are formed from any of Cu, Ag, Au, Sn, Ti, and mixtures and alloys thereof.

In step 130 shown in FIG. 3D, the photoresist layer 122 is stripped away, and a dielectric coating 132 is deposited on the first major surface 106 of the glass panel 104. As shown in FIG. 3D, the dielectric coating layer 132 has a thickness T that is less than or equal to the height h of the conductive pillars 124 above the first major surface 106. If necessary, a chemical mechanical polishing (CMP) process may be used to thin the dielectric coating layer 132 and reveal bonding pad portions 133 of the conductive pillars 124 that extend above the dielectric coating layer 132. The bonding pad portions terminate in contact regions 134.

In some examples, the first major surface 106 of the glass panel 104 may optionally be surface treated or include at least one coating layer (not shown in FIG. 3D) such as, for example, a primer layer or an adhesive layer, to improve bonding to the dielectric coating 132.

In some examples, the dielectric coating 132 is chosen from an inorganic material including Si, C. N and mixtures and combinations thereof. In some examples, the dielectric coating 132 is chosen from SiOₓ, SiCN, SiN and mixtures and combinations thereof. In some examples, the dielectric coating layer 132 includes SiO₂.

In some examples, the dielectric coating 132 is an organic material including, but not limited to, polyimides, benzocyclobutene polymers, and mixtures and combinations thereof.

Referring now to FIG. 3E, in step 140 of the process 100, two glass panels 104A, 104B, made according to the process in FIGS. 3A-3D above, are pressed together along the direction indicated by the arrows A, B. When the glass panels 104A, 104B are brought together, the facing dielectric layers 132A, 132B contact each other, and the contact regions 134A, 134B on the corresponding conductive pillars 124A, 124B also contact each other.

In some examples, the glass panels 104A, 104B and the conductive pillars 124A, 124B may be precisely aligned using corresponding fiducial structures on the glass panels 104A, 104B (not shown in FIG. 3E).

Referring to FIG. 3F, in step 150 the glass panels 104A, 104B are then subjected to a hybrid bonding process such that the dielectric layers 134A, 134B bond together to form a dielectric interface layer 152. The contact regions 134A, 134B in each corresponding conductive pillar 124A, 124B also abut each other to form a unitary workpiece construction 155 with continuous conductive pillars 154.

As noted above, in the hybrid bonding process, the dielectric layers 134A, 134B are contacted at room temperature (about 20° ° C. to about 30° C.) and functional groups on the facing surfaces thereof bond to form the dielectric interface layer 152. Then the construction 155 is annealed at a temperature of about 100° ° C. to about 500° C. or about 200° ° C. to about 400° C. This combination of room temperature bonding and higher temperature bonding with annealing causes the contact regions 134A, 134B to directly contact each other, and the abutting conductive pillars 124A, 124B form substantially continuous conductive pillars 154.

As shown in FIG. 3F, the conductive pillars 154 extend from a first major surface 156 to a second major surface 158 of the unitary workpiece 155. The conductive pillars 154 have a first diameter D₁ at the major surfaces 156, 158, and a second diameter D₂ within the dielectric interface layer 152, wherein D₁<D₂. Since the conductive pillars 154 do not “neck down” between the first major surface 156 and the second major surface 158 of the workpiece 155, current flow through the pillars 154 is improved, and heating of the glass layers 104A, 104B can be reduced at higher current levels.

FIG. 3G outlines a method 160 for making a glass substrate suitable for mounting a semiconductor device.

Step 162 of the method 160 includes forming a first plurality of conductive pillars in a first glass panel, wherein the first glass panel includes a first dielectric layer.

Step 164 of the method 160 includes forming a second plurality of conductive pillars in a second glass panel, wherein the second glass panel includes a second dielectric layer.

Step 166 of the method 160 includes bonding the first dielectric layer to the second dielectric layer to form a dielectric interface layer, wherein the first plurality of conductive pillars are electrically interconnected with the second plurality of conductive pillars, and wherein the first plurality of conductive pillars and the second plurality of conductive pillars taper from a first diameter in the dielectric interface layer to a second diameter in the first glass layer and the second glass layer, and wherein the first diameter is greater than the second diameter.

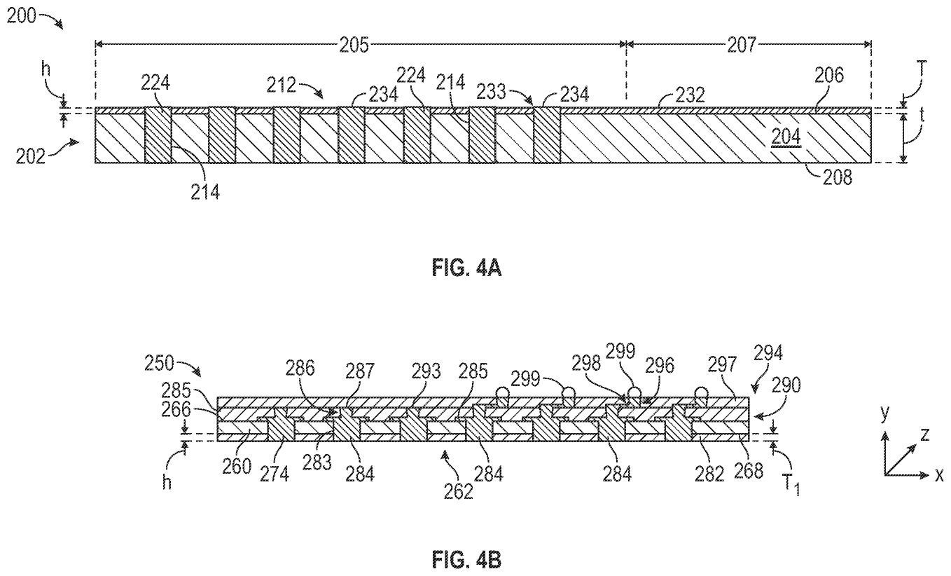

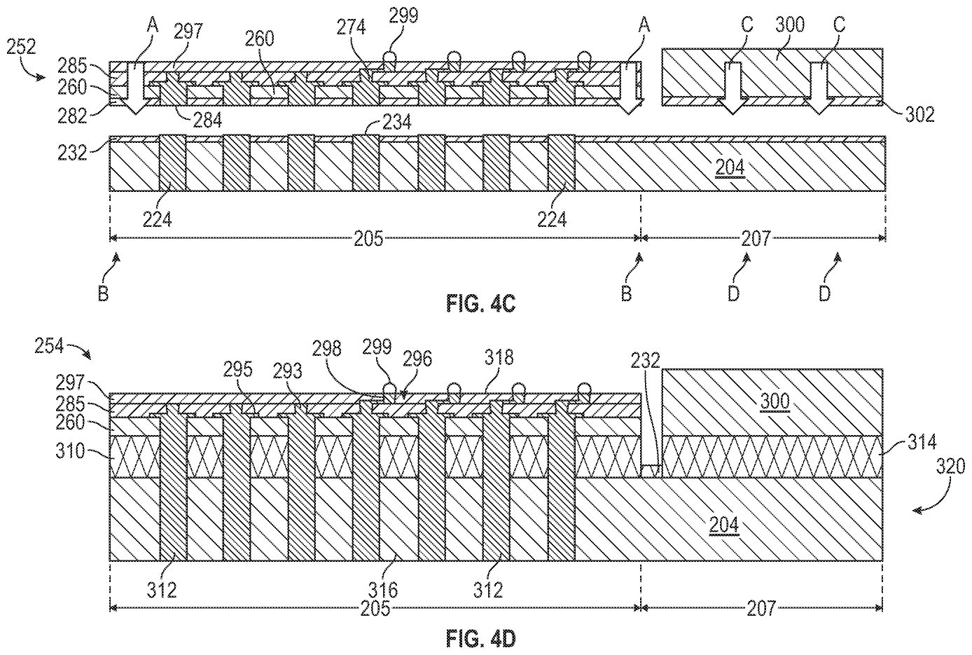

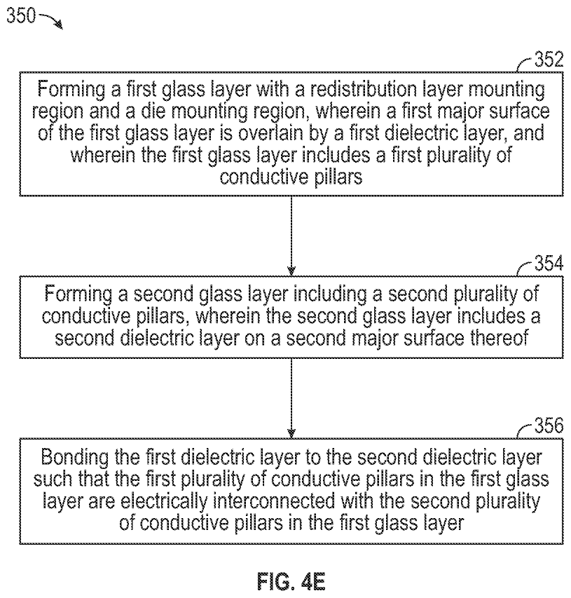

Referring now to FIG. 4A, a process 200 is shown in which hybrid bonding techniques are used to make an integrated circuit package suitable for mounting an integrated circuit device such as, for example, a photonic integrated circuit device. In step 202 of the process 200, a first glass core panel 204 includes a first major surface 206 and a second major surface 208. The first major surface 206 and the second major surface 208 of the glass panel 204 are planar and substantially flat, and substantially parallel to each other. In some examples, the glass panel 204 has a thickness/of about 300 microns to about 600 microns, or about 400 microns to about 500 microns.

The first glass panel 204 may be made of any suitable glass, including pure silica (e.g., approximately 100% SiO₂), soda-lime glass, boro-silicate glass, alumo-silicate glass, and the like. In some examples, the first glass panel may be made from fluoride glasses, phosphate glasses, chalcogen glasses, etc.) may also be used, and may include other materials or additives as discussed above with respect to the glass panel 104 in FIG. 3A.

The first glass panel 204 includes a redistribution layer (RDL) mounting region 205 and a photonic integrated circuit device (PIC) mounting region 207. The RDL mounting region 205 includes an array 212 with a plurality of vias 214. The vias 214 may be formed by any suitable procedure, and in some examples may be formed by laser drilling, or by laser treatment of the first glass panel 204 followed by wet or dry etching the glass panel 204 to provide vias 214 of a desired aspect ratio. In one example, following laser treatment of a surface of the first glass panel 204, a reactive ion etching step is performed to create the plurality of vias 214. In some examples, the first glass panel 204 may be mounted on or supported in a jig or a carrier (not shown in FIG. 4A) during via formation.

As shown in FIG. 4A, the vias 214 extend from the first major surface 206 to the second major surface 208 in the RDL region 205 of the first glass panel 204. In some examples, which are not intended to be limiting, the vias 214 in the array 212 have a pitch of less than about 50 microns, or less than about 20 microns, or less than about 10 microns, or less than about 5 microns.

In some examples, the vias 214 may be made as discussed above in the discussion of FIGS. 3B-3D. A photoresist layer is applied on the first major surface 206 of the first glass panel 204, and seed layers of a conductive material such as, for example. Cu, are deposited in the vias 214 and melted to form conductive pillars 224 therein. The conductive pillars 224 extend from the first major surface 206 to the second major surface 208 of the first glass panel 204, and extend to a height h above the first major surface 206. The conductive pillars 224 may be formed from any conductive material, and in some examples the pillars 224 are formed from any of Cu, Ag, Au, Sn, Ti, and mixtures and alloys thereof.

In some examples (not shown in FIG. 4A), the RDL mounting region 215 may include multiple glass layers and un-necked conductive pillars such as those illustrated in FIG. 3F herein.

After a photoresist layer (not shown in FIG. 4A, see FIG. 3C for an example) used to form the pillars 224 is stripped away, a dielectric coating 232 is deposited on the first major surface 206 of the first glass panel 204. As shown in FIG. 4A, the dielectric coating 232 overlies both the RDL mounting region 205 and the die mounting region 207 of the first glass panel 204. The dielectric coating layer 232 has a thickness T that is less than or equal to the height h of the conductive pillars 224 above the first major surface 206. If necessary, a chemical mechanical polishing (CMP) process may be used to thin the dielectric coating layer 232 and reveal bonding pad portions 233 of the conductive pillars 224 that extend above the dielectric coating layer 232. The bonding pad portions terminate in contact regions 234.

In some examples, the first major surface 206 of the first glass panel 204 may optionally be surface treated or include at least one coating layer (not shown in FIG. 4A) such as, for example, a primer layer or an adhesive layer, to improve bonding to the dielectric coating 232.

In some examples, the dielectric coating 232 is chosen from an inorganic material including Si, C, N and mixtures and combinations thereof. Suitable materials for the dielectric coating 232 include, but are not limited to, SiOₓ, SiCN, SiN and mixtures and combinations thereof. In some examples, the dielectric coating 132 includes SiO₂. In some examples, the dielectric coating 232 is an organic material including, but not limited to, polyimides, benzocyclobutene polymers, and mixtures and combinations thereof.

Referring now to FIG. 4B, in step 250 of the process 200, a second glass layer 260 includes a first major surface 266 and an opposed second major surface 268. As further detailed below, the second glass layer 260 is configured to overlie the RDL mounting region 205 of the first glass layer 204.

The second glass layer 260 includes an array 262 of conductive pillars 274. The conductive pillars 274 extend from the first major surface 266 to the second major surface 268 of the second glass panel 260, and extend to a height h₁ above the first major surface 266 thereof. The conductive pillars 274 may be formed from any conductive material, and in some examples the pillars 274 are formed from any of Cu, Ag, Au, Sn, Ti, and mixtures and alloys thereof.

A dielectric layer 282 resides on the second major surface 268 of the second glass layer 260, and may include any of the inorganic or organic dielectric materials discussed above with reference to the dielectric layer 232 in FIG. 4A. The dielectric layer 282 has a thickness T₁ that is less or equal to the height h of the conductive pillars 274 above the first major surface 266. A chemical mechanical polishing (CMP) process may be used if needed to thin the dielectric coating layer 282 and reveal bonding pad portions 283 of the conductive pillars 274 that extend above the dielectric coating layer 282. The bonding pad portions 283 terminate in contact regions 284.

An interconnect layer 290 resides on the first major surface 266 of the second glass layer 260. The interconnect layer 290 includes a dielectric layer 285, which may include any of the inorganic or organic dielectric materials discussed above with reference to the dielectric layer 232 in FIG. 4A. At least a portion of the conductive pillars 274 include interconnect structures 286 that are flush with, or extend beyond, the thickness of the dielectric layer 285 and form conductive contacts 287. As shown in FIG. 4B, the interconnect structures 286 may include a wide variety of conductive traces extending along any of the x, y, and z directions as needed to make electrical connections to the pillars 274.

A redistribution layer (RDL) 294 resides on the interconnect layer 290. The RDL 294 includes a dielectric layer 297 and conductive interconnect structures 296, at least some of which terminate in solder bump mounts 298. The dielectric layer 297 may include any of the inorganic or organic dielectric materials discussed above with reference to the dielectric layer 232 in FIG. 4A. At least a portion of the solder bump mounts 298 are attached to solder bumps 299 suitable for connection to other dies, conductive traces and the like.

Referring now to FIG. 4C, in step 252 of the process 200, the second glass panel 260 is aligned over the RDL mounting region 205 on the first glass panel 204. The first glass panel 204 and the second glass panel 260 are pressed together along the direction indicated by the arrows A, B. When the glass panels 204, 260 are brought together, the dielectric layers 232, 282 contact each other, and the contact regions 234, 284 on the respective conductive pillars 224, 274 also abut each other.

In some examples, the glass panels 204, 260 and the conductive pillars 224, 274 may be precisely aligned using corresponding fiducial structures on the glass panels 204, 260 (not shown in FIG. 4C).

An integrated circuit device such as a photonic integrated circuit device 300 is aligned over the PIC mounting region 207 of the first glass panel 204. To prevent undesirable optical signal loss, the photonic integrated circuit device 300 should be precisely mounted on the first glass panel 204. The photonic integrated circuit device 300 includes a dielectric mounting layer 302 that may be made from any of the inorganic or organic dielectric materials discussed above with reference to the dielectric layer 232 in FIG. 4A. The photonic integrated circuit device 300 and the first glass panel 204 are pressed together along the direction indicated by the arrows C, D. When the photonic integrated circuit device 300 and the first glass panel 204 are brought together, the dielectric layer 232 and the dielectric mounting layer 302 contact each other.

Referring to FIG. 4D, in step 254 the first and the second glass panels 204, 260 are then subjected to a hybrid bonding process such that the respective dielectric layers 232, 282 thereon bond to form a dielectric interface layer 310. The contact regions 234, 284 abut on corresponding conductive pillars 224, 274 to form a unitary workpiece construction 320 with continuous conductive pillars 312.

As discussed above, in the hybrid bonding process, the dielectric layers 232, 282 are contacted at room temperature (about 20° C. to about 30° C.) in the RDL bonding region 205 of the first glass panel 204 and bond to form the interface layer 310. Then the construction 320 is annealed at a temperature of about 100° ° C. to about 500° ° C., or about 200° ° C. to about 400° ° C. This combination of room temperature bonding and higher temperature bonding and annealing causes the contact regions 234, 284 to directly abut each other, forming substantially continuous conductive pillars 312. As shown in FIG. 4D, the conductive pillars 312 form continuous structures that extend from a first major surface 316 to a second major surface 318 of the bonded unitary workpiece 320.

During the hybrid bonding process, at the same or a different time than the bonding step joining the dielectric layers 232, 282, the photonic integrated circuit device 300 is placed on the PIC mounting region 207 of the first glass panel 204 such that the dielectric mounting layer 302 contacts the dielectric layer 232 on the first glass panel. Following initial contact at room temperature, during the annealing step the abutting dielectric layers 302, 232 bond together to form an interface layer 314 and electrically connect the photonic integrated circuit device 300 to the first glass panel 204.

In some examples, either one or both of the photonic integrated circuit device 300 and the glass substrate 204 may include additional adhesive layers, bonding pads, conductive traces and the like (not shown in FIG. 4D) to enhance the integrity of the bond between the photonic integrated circuit device 300 and the first glass panel 204.

In some examples, the process of FIG. 4D can obviate the need to form cavities in the first glass layer 204 or the second glass layer 260, or can reduce the number of required cavities in the glass layers 204, 260, which can reduce or eliminate contamination of the glass layers 204, 260 during downstream process steps. The second glass layer 260 carrying the RDL structures and the photonic integrated circuit device 300 are mounted on the same planar dielectric layer 232, which simplifies component alignment and enhances reliability and reproducibility.

FIG. 4E illustrates a method 350 for making a glass substrate suitable for mounting a semiconductor device.

Step 352 of the method 350 includes forming a first glass layer with a redistribution layer mounting region and a PIC mounting region, wherein a first major surface of the first glass layer is overlain by a first dielectric layer, and wherein the first glass layer includes a first plurality of conductive pillars.

Step 354 of the method 350 includes forming a second glass layer including a second plurality of conductive pillars, wherein the second glass layer includes a second dielectric layer on a second major surface thereof.

Step 356 of the method 350 includes bonding the first dielectric layer to the second dielectric layer such that the first plurality of conductive pillars in the first glass layer are electrically interconnected with the second plurality of conductive pillars in the first glass layer.

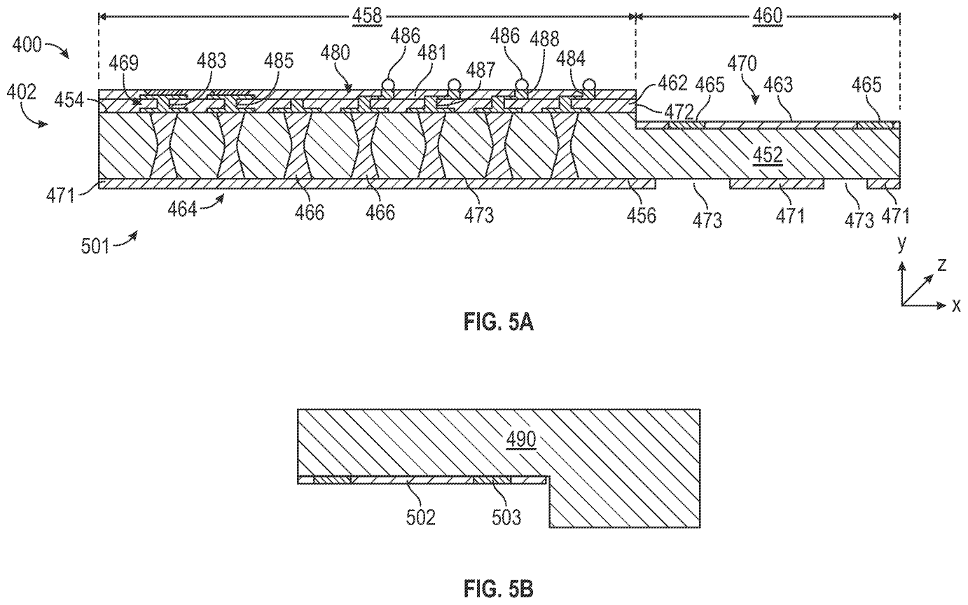

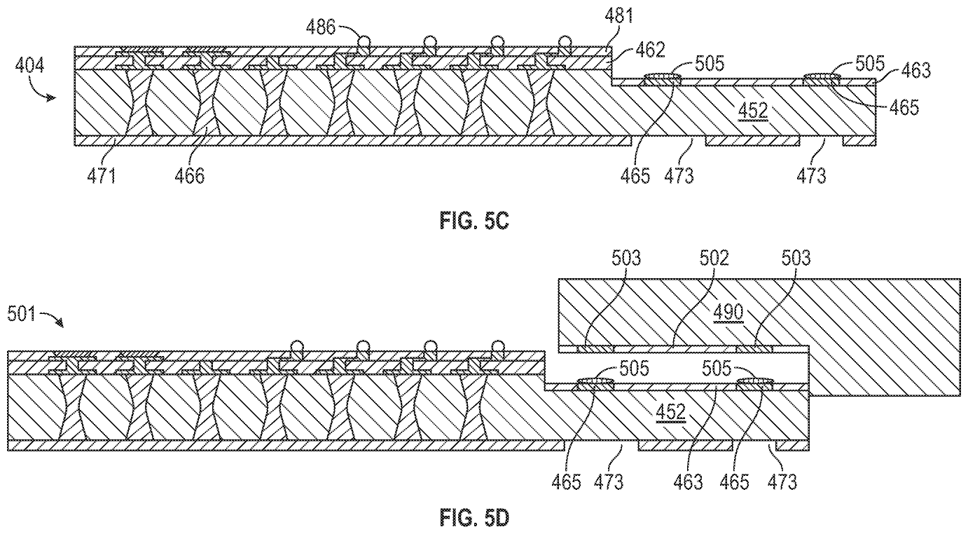

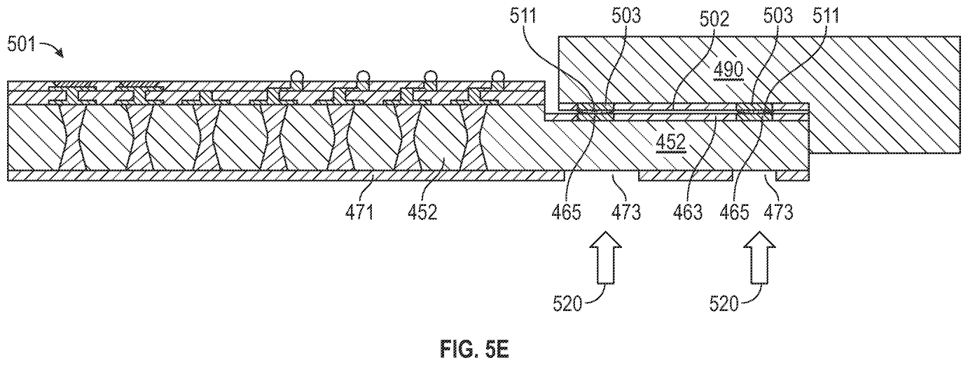

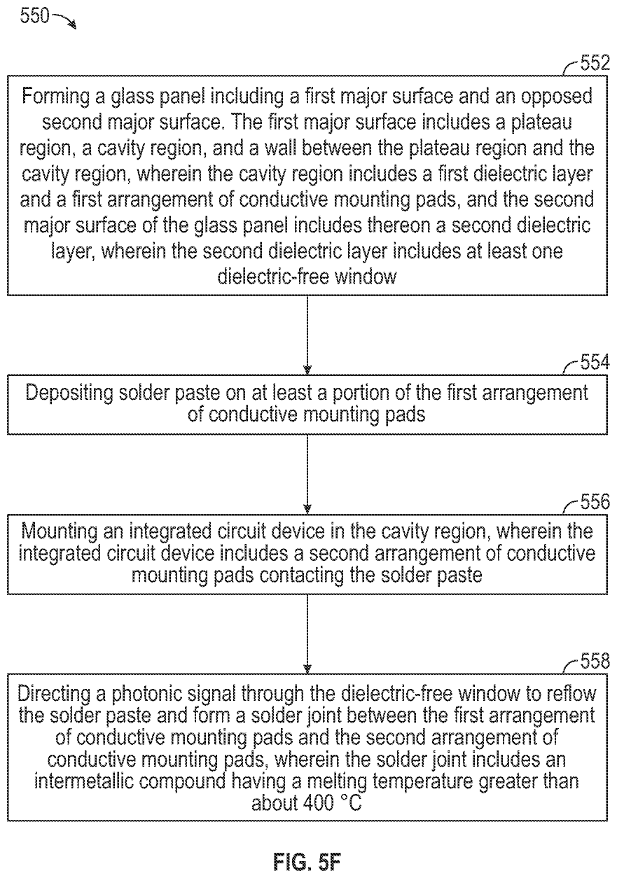

Referring now to FIG. 5A, a process 400 is illustrated for mounting an integrated circuit device such as, for example, a photonic integrated circuit device, in a cavity or in a designated region of a glass substrate. As shown in FIG. 5A, a workpiece 501 includes a glass core substrate 452 with a first major surface 454 and an opposed second major surface 456. The first major surface 454 includes a redistribution layer (RDL) mounting region 458 and a photonic integrated circuit device (PIC) mounting region 460.

A first dielectric layer 462 overlies the RDL mounting region 458. A second dielectric layer 463 overlies the PIC module mounting region 460. The dielectric layers 462, 463 may include any of the inorganic or organic dielectric materials discussed above with reference to the dielectric layer 232 in FIG. 4A. In some examples, the dielectric layers 462, 463 are formed from an organic dielectric material such as a polyimide.

The second dielectric layer 463 further includes an arrangement of conductive contacts 465. In the example of FIG. 5A, the conductive contacts 465 reside in the xz plane on the first major surface 454, and may include conductive traces, bars, solder balls, and combinations thereof configured to mount a selected photonic integrated circuit device in the PIC mounting region 460.

The RDL mounting region 458 includes a plurality of conductive pillars 466 in an array 464 that extend from the first major surface 454 to the second major surface 456. In some examples (not shown in FIG. 5A), the RDL mounting region 458 may include multiple glass layers and un-necked conductive pillars such as those illustrated in FIG. 3F herein. At least a portion of the conductive pillars 466 include interconnect structures 469 that extend beyond the first dielectric layer 462. As shown in FIG. 5A, the interconnect structures 469 may include a wide variety of conductive elements extending along any of the x, y, and z directions as needed to make electrical connections to the pillars 466, and the elements shown in FIG. 5A are merely provided as examples. For example, the conductive interconnect structures may include posts 483 extending along the y direction, linear bars 485 extending along the z direction, traces 487 extending along the x, y or z direction, or any combination thereof necessary to mount one or more integrated circuit devices on the overlying RDL 480.

The PIC mounting region 460 includes a cavity 470 in the glass substrate 452, which in some examples is optionally at least partially bounded by a wall 472.

A redistribution layer (RDL) 480 resides on the RDL mounting region 458 of the glass substrate 452. The RDL 480 includes a dielectric layer 481 and conductive interconnect structures 488, at least some of which terminate in solder bump mounts 484. At least a portion of the solder bump mounts 484 are attached to solder bumps 486 suitable for connection to other dies, conductive traces and the like. The dielectric layer 481 may include any of the inorganic or organic dielectric materials discussed above with reference to the dielectric layer 232 in FIG. 4A.

A dielectric layer 471 resides on the second major surface 456 of the glass panel 452. The dielectric layer 471 may include any of the inorganic or organic dielectric materials discussed above with reference to the dielectric layer 232 in FIG. 4A. The dielectric layer 471 does not overlie the entirety of the second major surface 456 of the glass panel 452, but instead includes an arrangement of dielectric-free regions that form light transmissive windows 473. The position and size of the windows 473 may vary widely depending on the intended application, but in some examples the windows 473 are configured to underlie the conductive contacts 465 in the PIC mounting region 460 of the glass panel 452.

As shown in FIG. 5B, a photonic integrated circuit device 490 is configured for mounting in the PIC mounting region 460 of the glass substrate 452 in the workpiece 501 of FIG. 5A. In the example of FIG. 5B, the photonic integrated circuit device 490 may be mounted in the cavity 470 along the wall 472. The photonic integrated circuit device 490 includes a dielectric mounting layer 502, which has embedded therein an arrangement of conductive structures 503. The conductive structures 503 may vary widely, but in some examples are conductive bars, solder balls and the like configured to engage with the conductive contacts 465 in the dielectric layer 463 on the glass panel 452.

Referring now to FIG. 5C, in step 404 of the method 400 a conductive solder paste 505 is deposited on the conductive contacts 465 in the dielectric layer 463 on the glass panel 452 of the workpiece 501. The solder paste 505 includes a composition with metals chosen to form an intermetallic compound when a solder formed from the solder paste 505 is reflowed in a downstream process step.

As shown in FIG. 5D, in step 406 of the process 400, the photonic integrated circuit device 490 of FIG. 5B is then brought into contact with the substrate 501 such that the conductive contacts 503 thereon contact the solder paste 505.

Referring to FIG. 5E, photonic signals 520 are directed through the windows 473 in the workpiece 501. The photonic signals 520 traverse the glass substrate 452, which is transmissive to broadband light with a wavelength of about 200 nm to about 1500 nm, and are absorbed by one or both of the dielectric layers 463, 502. The temperature of the dielectric layers 463, 502 rapidly increases, which causes the solder paste 505 to melt and reflow, forming a solder joint 511 including an intermetallic compound.

In some examples, which are not intended to be limiting, the photonic signals 520 include intense pulsed light from a short (0.03-100 ms) pulse of broadband light (200-1,500 nm), which is converted to heat selectively within the light-absorbing layers 463, 502, resulting in rapid transformations and reactions. While the intensity of the photonic signals 520 is high, the total energy is low because of the short pulse duration, and as such the photonic heating step can have a shorter processing time compared to thermal annealing, and is compatible with a wide variety of transparent glass substrates.

In some examples, which are not intended to be limiting, the photonic signals 520 can be generated with a system that includes a 500 V lamp driver, 1.5 kW power supply, and 20 mm (diameter)×150 mm (length) xenon flash lamp (75 mm×150 mm illumination area). Photonic curing can easily be performed under ambient conditions.

The heating of at least one of the dielectric layers 463, 502 via the photonic signals 520 is of sufficient intensity and duration to cause the solder paste 505 to melt and reflow, which forms the solder joint 511. The solder joint 511 includes an intermetallic compound having a melting temperature of greater than about 400° C., or greater than about 500° ° C. The high melting intermetallic joint 511 is resistant to melting or reflow in downstream process steps, which can preserve the electrical conductivity of the solder joint 511 between the workpiece 501 and the photonic integrated circuit device 490. The resistance to melting and reflow of the solder joint 511 including the intermetallic compound can also help to maintain the position accuracy of the bonded integrated circuit device.

In this application, the term intermetallic compound refers to ordered alloys of two or more metals having a definite stoichiometry. Intermetallic compounds are formed from electropositive and electronegative metals that chemically bond to form compounds with a specific composition and crystalline structure.

In some examples, the solder paste 505 includes elemental metals chosen from Cu, In, Sn, Bi, and mixtures and combinations thereof. In some examples, which are not intended to be limiting, the solder paste 505 includes metals in amounts chosen to form, upon reflow of the solder paste 505, a CuₓSn_{y} intermetallic compound, a NiₓSn_{y} intermetallic compound, or mixtures and combinations thereof, in the solder joint 511. In another example, the solder paste 505 includes Cu particles in combination with at least one of Sn particles or Bi particles, and upon reflows forms a solder joint 511 including Cu₃Sn intermetallic compounds.

Each of the intermetallic compounds formed upon reflow of the solder paste 505 have a melting temperature of greater than about 400° C. The melting temperature can be measured by any suitable technique such as, for example, differential scanning calorimetry (DSC). In some examples, which are not intended to be limiting, the melting temperature measurement made using DSC instruments can have a temperature precision of ±0.005° C. and a temperature repeatability of ±0.025° C.

In some examples, the solder paste 505 may optionally include metallic additives such Bi, In, and mixtures and combinations thereof to facilitate formation of the intermetallic compound in the solder joint 511 at a lower temperature. In some examples, the solder paste 505 may optionally include additives such as fluxes and the like that are chosen to assist in the formation of the solder joint 511, or to facilitate formation of the intermetallic compound therein. For example, suitable fluxes can remove metal oxides to promote the reaction between the elemental metal components to form the intermetallic compound in the solder joint 511.

The transparency of the glass substrate to the photonic signals 520 allows windows 473 to be easily and accurately oriented on the workpiece 501, and the photonic heating process is highly rapid and efficient compared to annealing processes in which the entire workpiece 501 is heated to cause reflow of the solder paste 505. The site-specific heating from the photonic signals 520 also reduces or eliminates damage to components caused by an annealing step in which the entire workpiece 501 is heated.

FIG. 5F is directed to a method 550 for attaching a semiconductor device to a substrate.

Step 552 of the method 550 includes forming a glass panel including a first major surface and an opposed second major surface. The first major surface includes a plateau region, a cavity region, and a wall between the plateau region and the cavity region. The cavity region includes a first dielectric layer and a first arrangement of conductive mounting pads. The second major surface of the glass panel includes thereon a second dielectric layer, wherein the second dielectric layer includes at least one dielectric-free window.

Step 554 of the method 550 includes depositing solder paste on at least a portion of the first arrangement of conductive mounting pads.

Step 556 of the method 550 includes mounting an integrated circuit die in the cavity region, wherein the integrated circuit die includes a second arrangement of conductive mounting pads contacting the solder paste.

Step 558 of the method 550 includes directing a photonic signal through the dielectric-free window to reflow the solder paste and form a solder joint between the first arrangement of conductive mounting pads and the second arrangement of conductive mounting pads, wherein the solder joint includes an intermetallic compound and has a melting temperature greater than about 400° C.

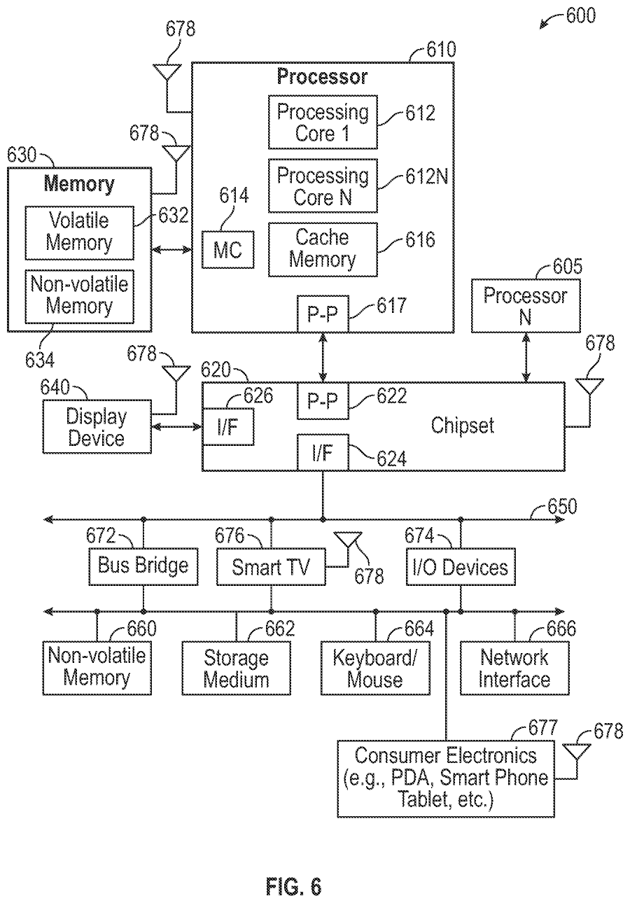

FIG. 6 illustrates a system level diagram, depicting an example of an electronic device (e.g., system) that may include a workpiece made using the processes described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance, or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as those available from Intel, Santa Clara, CA, under the trade designation QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O) devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described to best explain the principles involved and their practical applications, to thereby enable others skilled in the art to best utilize the various example embodiments with various modifications as are suited to the particular use contemplated.

It will also be understood that, although the terms “first.” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a.” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

### Examples

Example A. An integrated circuit device substrate, comprising:
   a first glass layer;
   a second glass layer;
   a dielectric interface layer between the first glass layer and the second glass layer; and
   a plurality of conductive pillars extending through the first glass layer, the dielectric layer and the second glass layer, wherein the conductive pillars taper from a first diameter in the dielectric layer to a second diameter in the first glass layer and the second glass layer, and wherein the first diameter is greater than the second diameter.
Example B. The substrate of Example A, wherein the dielectric interface layer comprises an inorganic material chosen from Si, C, N and mixtures and combinations thereof.
Example C. The substrate of Example B, wherein the inorganic material is SiOₓ.
Example D. The substrate of any of Examples A to C, wherein the dielectric interface layer comprises a polymeric material chosen from benzocyclobutene polymers, and mixtures and combinations thereof.
Example E. The substrate of any of Examples A to D, wherein the first glass layer and the second glass layer are independently chosen from SiO₂, soda-lime glass, boro-silicate glass, and alumo-silicate glass.
Example F. The substrate of any of Examples A to E, wherein the first glass panel and the second glass panel each have a thickness of less than about 500 microns.
Example G. An integrated circuit device substrate, comprising:
   a first glass panel;
   a second glass panel;
   a dielectric interface layer between the first glass panel and the second glass panel; and
   a plurality of conductive pillars extending through the first glass layer, the dielectric interface layer and the second glass layer, wherein the conductive pillars taper from a first diameter in the dielectric interface layer to a second diameter in the first glass layer and the second glass layer, and wherein the first diameter is greater than the second diameter.
Example H. The substrate of Example G, wherein the dielectric interface layer is chosen from SiOₓ and polyimides.
Example I. The substrate of any of Examples G or H, wherein the first glass panel and the second glass panel each have a thickness of less than about 500 microns.
Example J. The substrate of any of Examples G to I, further comprising an integrated circuit device electrically interconnected with the conductive pillars.
Example K. The substrate of any of Examples G to J, wherein the first glass layer and the second glass layer are independently chosen from SiO₂, soda-lime glass, boro-silicate glass, and alumo-silicate glass.
Example L. A method for making a glass substrate suitable for mounting an integrated circuit device, the method comprising:
   forming a first plurality of conductive pillars in a first glass panel, wherein the first glass panel comprises a first dielectric layer;
   forming a second plurality of conductive pillars in a second glass panel, wherein the second glass panel comprises a second dielectric layer;
   bonding the first dielectric layer to the second dielectric layer to form a dielectric interface layer, wherein the first plurality of conductive pillars are electrically interconnected with the second plurality of conductive pillars, and wherein the first plurality of conductive pillars and the second plurality of conductive pillars taper from a first diameter in the dielectric interface layer to a second diameter in the first glass layer and the second glass layer, and wherein the first diameter is greater than the second diameter.
Example M. The method of Example L, further comprising aligning the first array of conductive pillars with the second array of conductive pillars prior to the bonding step.
Example N. The method of Example L or M, wherein the aligning comprises registering a first fiducial on the first glass panel with a second fiducial on the second glass panel.
Example O. The method of any of Examples L to N, wherein either or both of the first plurality of conductive pillars and the second plurality of conductive pillars are formed within vias induced by a laser.
Example P. The method of any of Examples L to O, wherein the bonding comprises contacting the first dielectric layer and the second dielectric layer at room temperature and subsequently annealing the glass substrate at about 100° C. to about 500° C.

We claim:

1. An integrated circuit device substrate, comprising:
a first glass layer,
a second glass layer;
a dielectric interface layer between the first glass layer and the second glass layer; and
a plurality of conductive pillars extending through the first glass layer, the dielectric layer and the second glass layer, wherein the conductive pillars taper from a first diameter in the dielectric layer to a second diameter in the first glass layer and the second glass layer, and wherein the first diameter is greater than the second diameter.

2. The substrate of claim 1, wherein the dielectric interface layer comprises an inorganic material chosen from Si, C, N and mixtures and combinations thereof.

3. The substrate of claim 2, wherein the inorganic material is SiOₓ.

4. The substrate of claim 1, wherein the dielectric interface layer comprises a polymeric material chosen from benzocyclobutene polymers, and mixtures and combinations thereof.

5. The substrate of claim 1, wherein the first glass layer and the second glass layer are independently chosen from SiO₂, soda-lime glass, boro-silicate glass, and alumo-silicate glass.

6. The substrate of claim 1, wherein the first glass panel and the second glass panel each have a thickness of less than about 500 microns.

7. An integrated circuit device substrate, comprising:
a first glass panel;
a second glass panel;
a dielectric interface layer between the first glass panel and the second glass panel; and
a plurality of conductive pillars extending through the first glass layer, the dielectric interface layer and the second glass layer, wherein the conductive pillars taper from a first diameter in the dielectric interface layer to a second diameter in the first glass layer and the second glass layer, and wherein the first diameter is greater than the second diameter.

8. The substrate of claim 7, wherein the dielectric interface layer is chosen from SiOₓ and polyimides.

9. The substrate of claim 7, wherein the first glass panel and the second glass panel each have a thickness of less than about 500 microns.

10. The substrate of claim 7, further comprising an integrated circuit device electrically interconnected with the conductive pillars.

11. The substrate of claim 7, wherein the first glass layer and the second glass layer are independently chosen from SiO₂, soda-lime glass, boro-silicate glass, and alumo-silicate glass.

12. A method for making a glass substrate suitable for mounting an integrated circuit device, the method comprising:
forming a first plurality of conductive pillars in a first glass panel, wherein the first glass panel comprises a first dielectric layer;
forming a second plurality of conductive pillars in a second glass panel, wherein the second glass panel comprises a second dielectric layer;
bonding the first dielectric layer to the second dielectric layer to form a dielectric interface layer, wherein the first plurality of conductive pillars are electrically interconnected with the second plurality of conductive pillars, and wherein the first plurality of conductive pillars and the second plurality of conductive pillars taper from a first diameter in the dielectric interface layer to a second diameter in the first glass layer and the second glass layer, and wherein the first diameter is greater than the second diameter.

13. The method of claim 12, further comprising aligning the first array of conductive pillars with the second array of conductive pillars prior to the bonding step.

14. The method of claim 13, wherein the aligning comprises registering a first fiducial on the first glass panel with a second fiducial on the second glass panel.

15. The method of claim 12, wherein either or both of the first plurality of conductive pillars and the second plurality of conductive pillars are formed within vias induced by a laser.

16. The method of claim 12, wherein the bonding comprises contacting the first dielectric layer and the second dielectric layer at room temperature and subsequently annealing the glass substrate at about 100° ° C. to about 500° C.
